(19) United States
(12) Patent Application Publication
(10) Pub. No.: US 2026/0173624 A1
(43) Pub. Date: Jun. 18, 2026

(54) SEMICONDUCTOR DEVICE

(71) Applicant: Lextar Electronics Corporation, Hsinchu City (TW)

(72) Inventors: Shiou-Yi KUO, Hsinchu City (TW); Jian-Chin LIANG, Hsinchu City (TW)

(21) Appl. No.: 19/420,394

(22) Filed: Dec. 15, 2025

(30) Foreign Application Priority Data
Dec. 16, 2024 (TW) 113149001

(51) Int. Cl. H10H 29/853; H10F 39/90; H10F 77/00; H10F 77/50; H10H 29/20; H10H 29/85

(52) U.S. Cl. CPC H10H 29/853; H10F 39/90; H10F 77/50; H10F 77/933; H10H 29/20; H10H 29/857

(57) ABSTRACT

A semiconductor device includes a driving element, a light-emitting element, a light-sensing element, a cover layer, first electrical connecting layers, and second electrical connecting layers. The light-emitting element and the light-sensing element are arranged side by side on the driving element. The cover layer covers the light-emitting element, the light-sensing element, and the driving element. The first electrical connecting layers and the second electrical connecting layers are arranged between the cover layer and the driving element. The light-emitting element is connected to the driving element via the first electrical connecting layers and the light-sensing element is connected to the driving element via the second electrical connecting layers. The cover layer includes a first opening and a second opening. The first opening is arranged on the light-emitting element to expose the light-emitting element. The second opening is arranged on the light-sensing element to expose the light-sensing element.

### CROSS-REFERENCE TO RELATED APPLICATION

This application claims priority to Taiwan Application Serial Number 113149001, filed Dec. 16, 2024 which is herein incorporated by reference in its entirety.

### BACKGROUND

### Field of Disclosure

The present disclosure relates to a semiconductor device, and more particularly to a semiconductor device including a driving element, a light-emitting element, and a light-sensing element.

### Description of Related Art

Optoelectronic components have been widely used in various electronic devices. For example, semiconductor materials containing Group III and Group V elements can be used in various optoelectronic components, such as light-emitting chips (e.g., light-emitting diodes or laser diodes), photosensitive chips (e.g., photodiodes or solar cells), or power components (e.g., switches or rectifiers), which are utilized in lighting, medical, display, automotive, communication, sensing, power supply systems and other fields. In the sensing applications, optoelectronic components such as light-emitting chips and photosensitive chips are generally placed in a unitary package and then combined with a driver chip to form a sensing electronic device. With the trend of gradual scaling down for various components in electronic devices, the process difficulties have been greatly increased, resulting in issues such as low yield. Therefore, existing optoelectronic components, which have generally met various requirements, are not satisfactory in all aspects and still need further improvement.

### SUMMARY

In some embodiments of the present disclosure, a semiconductor device is provided. The semiconductor device includes a driving element, a light-emitting element, a light-sensing element, a cover layer, multiple first electrical connecting layers, and multiple second electrical connecting layers. The light-emitting element and the light-sensing element are arranged side by side on the driving element. The cover layer covers the light-emitting element, the light-sensing element, and the driving element. The first electrical connecting layers and the second electrical connecting layers are arranged between the cover layer and the driving element. The light-emitting element is electrically connected to the driving element via the first electrical connecting layers and the light-sensing element is electrically connected to the driving element via the second electrical connecting layers. The cover layer includes a first opening and a second opening. The first opening is arranged on the light-emitting element to expose a part of the light-emitting element, and the second opening is arranged on the light-sensing element to expose a part of the light-sensing element.

### BRIEF DESCRIPTION OF THE DRAWINGS

Through the following detailed description in conjunction with the accompanying drawings, understanding of the concepts of the embodiments of the present disclosure can be further enhanced. It should be noted that, according to standard industrial practice, some features may not be drawn to scale and are intended only for illustrative purposes. In fact, the dimensions of the components may be enlarged or reduced to clearly illustrate the technical features of the embodiments in the present disclosure.

FIG. 1 illustrates a top-view schematic diagram of a semiconductor device according to some embodiments of the present disclosure.

FIG. 2 illustrates a cross-sectional schematic diagram along line I-I in FIG. 1 according to some embodiments of the present disclosure.

FIG. 3 illustrates a partially enlarged schematic view of region A in FIG. 2 according to some embodiments of the present disclosure.

FIGS. 4A-4C are schematic diagrams illustrating the arrangement of the light-emitting elements and light-sensing elements on the driving element according to some embodiments of the present disclosure.

FIGS. 5A-5D are schematic diagrams illustrating the arrangement of the light-emitting elements and light-sensing elements on the driving element according to other embodiments of the present disclosure.

FIG. 6 is a schematic diagram illustrating an arrangement of the light-emitting elements, light-sensing elements, and driving elements on the carrier substrate according to some embodiments of the present disclosure.

### DETAILED DESCRIPTION

The following disclosure provides many different embodiments or examples for implementing various features of the present application. The following disclosure describes specific examples of various components and their arrangements, in order to simplify the explanation. Of course, these specific examples are not intended to be limiting. For example, if the embodiments of this disclosure describe a first feature component formed on or above a second feature component, this indicates that the embodiment may include cases where the first feature component and the second feature component are in direct contact, as well as cases where an additional feature component is formed between the first feature component and the second feature component, such that the first feature component and the second feature component may not be in direct contact.

It should be understood that additional operational steps may be performed before, during, or after the described methods, and in other embodiments of the described methods, some operational steps may be replaced or omitted.

In addition, spatially related terms may be used herein, such as “beneath”, “below”, “under”, “above”, “over”, “on”, and similar terms. These spatially related terms are used for convenience in describing the relationship between one or more elements or feature components and one or more other elements or feature components in the drawings. These spatially related terms include the different orientations of the device in use or operation, as well as the orientation described in the drawings. When the device is rotated into different orientations (for example, rotated 90 degrees or to other orientations), the spatially related adjectives used herein are to be interpreted in accordance with the orientation after rotation.

In the specification, the term “substantially” generally indicates within 20% of a given value or range, or within 10%, or within 5%, or within 3%, or within 2%, or within 1%, or within 0.5%. In the specifications, the given values are approximate values. That is, even in the absence of explicit use of the term “substantially,” the meaning of “substantially” may still be implied.

Unless otherwise defined, all terms used herein (including technical and scientific terms) have the same meaning as would normally be understood by one of ordinary skill in the art to which this disclosure pertains. It can be understood that these terms, for example, those defined in commonly used dictionaries, should be interpreted as having a meaning consistent with their relevant technical context and the context of this disclosure, and should not be interpreted in an idealized or overly formal sense, unless expressly defined in embodiments of this disclosure.

Different embodiments disclosed below may repeatedly use the same reference numerals and/or labels. Such repetition is for simplification and clarity, and is not intended to indicate that there is a specific relationship between the different embodiments and/or structures being discussed.

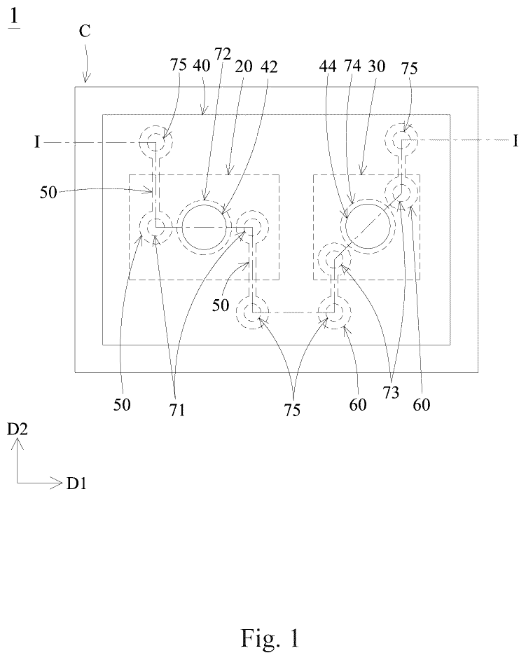

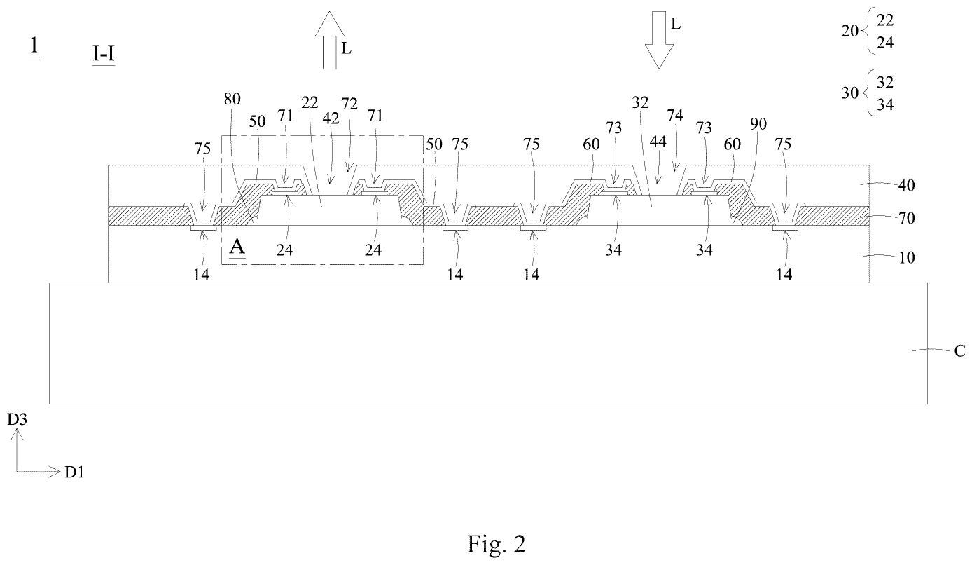

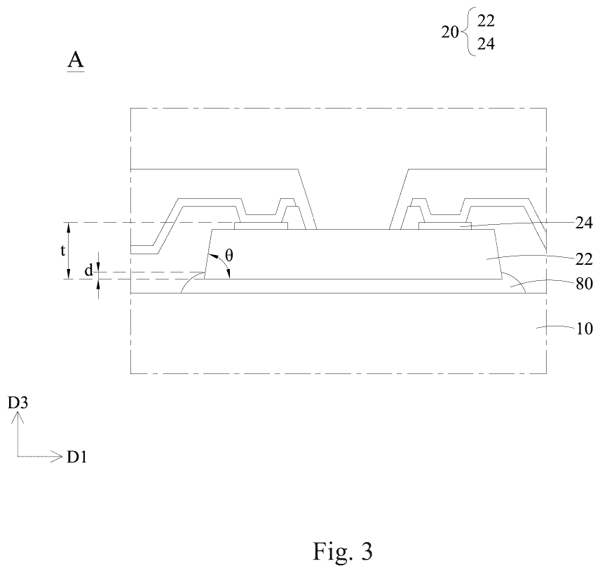

FIG. 1 is a top view schematic diagram of a semiconductor device 1 according to some embodiments of the present disclosure, FIG. 2 is a cross-sectional schematic diagram taken along line I-I of FIG. 1 according to some embodiments of the present disclosure, and FIG. 3 is an enlarged partial schematic view of region A in FIG. 2 according to some embodiments of the present disclosure. It should be noted that, for the sake of simplicity, some components of the semiconductor device 1 have been omitted in FIGS. 1, 2, and 3. In addition, FIGS. 1, 2, and 3 may not fully correspond to each other.

Referring to FIGS. 1 and 2, in some embodiments, the semiconductor device 1 includes a driving element 10, a light-emitting element 20, a light-sensing element 30, and a cover layer 40. Specifically, the light-emitting element 20 and the light-sensing element 30 are located on the driving element 10, and the cover layer 40 covers the light-emitting element 20, the light-sensing element 30, and the driving element 10.

In some embodiments, the driving element 10 is used to carry the light-emitting element 20 and the light-sensing element 30. Specifically, the light-emitting element 20 and the light-sensing element 30 are arranged on the driving element 10 along a first direction D1, and the light-emitting element 20 and the light-sensing element 30 are separated from each other. In some embodiments, the driving element 10 includes components that can control the light-emitting element 20 and the light-sensing element 30. For example, the driving element 10 may include an integrated circuit (IC). In some embodiments, the driving element 10 includes a plurality of driving contacts 14 located on the side of the driving element 10 facing the light-emitting element 20 and the light-sensing element 30. In some embodiments, the driving contacts 14 may include a conductive material such as metal, nitride, oxide, similar materials thereof, or combinations thereof. For example, the metal may includes gold (Au), nickel (Ni), platinum (Pt), palladium (Pd), iridium (Ir), titanium (Ti), chromium (Cr), tungsten (W), aluminum (Al), copper (Cu), beryllium (Be), germanium (Ge), zinc (Zn), tin (Sn), the alloy thereof, or combinations thereof. The nitride may include titanium nitride (TiN), and the oxide may include indium tin oxide (ITO) or indium zinc oxide (IZO).

In some embodiments, the light-emitting element 20 is a light source of the semiconductor device 1 and can emit a light beam L, and the light beam L may be visible light or invisible light. In some embodiments, the light-emitting element 20 may include a laser diode (LD). For example, the laser diode may be an edge emitting laser (EEL) or a vertical cavity surface emitting laser (VCSEL). In some embodiments, the light-emitting element 20 includes a light-emitting stacked layer 22 and a plurality of light-emitting contacts 24, the plurality of light-emitting contacts 24 being located on the same side of the light-emitting stacked layer 22. For example, the plurality of light-emitting contacts 24 are located on the side of the light-emitting stacked layer 22 that faces away from the driving element 10. In some embodiments, the material of the light-emitting stacked layer 22 may include a III-V compound semiconductor material. In some embodiments, the material of the light-emitting contact 24 may be the same as or similar to that of the driving contact 14. In some embodiments, the light-emitting element 20 is a thin-film element, that is, the light-emitting element 20 does not include a substrate, so as to facilitate thin applications. In some embodiments, the light-emitting element 20 is disposed on the driving element 10 by a mass transfer method.

In some embodiments, the light-sensing element 30 can receive the light beam L emitted by the light-emitting element 20. For example, the light-sensing element 30 may include a photodiode (PD). In some embodiments, the light-sensing element 30 includes a light-sensing stacked layer 32 and a plurality of light-sensing contacts 34, the plurality of light-sensing contacts 34 being located on the side of the light-sensing element 30 that faces away from the driving element 10. In some embodiments, the material of the light-sensing stacked layer 32 may include a III-V compound semiconductor material. In some embodiments, the material of the light-sensing contact 34 may be the same as or similar to that of the driving contact 14. In some embodiments, the light-sensing element 30 is a thin film element, that is, the light-sensing element 30 does not include a substrate, so as to facilitate thin applications. In some embodiments, the light-sensing element 30 is disposed on the driving element 10 by a mass transfer method.

In some embodiments, the cover layer 40 includes a first opening 42 and a second opening 44. The first opening 42 is disposed correspondingly on the light-emitting element 20 and exposes a portion of the light-emitting element 20 so that the light beam L emitted by the light-emitting element 20 can be emitted from the first opening 42. The second opening 44 is disposed correspondingly on the light-sensing element 30 and exposes a portion of the light-sensing element 30 so that the light-sensing element 30 can receive the light beam L from the second opening 44. In some embodiments, the first opening 42 is located between two light-emitting contacts 24, and the second opening 44 is located between two light-sensing contacts 34. In other words, the light-emitting contacts 24 and the light-sensing contacts 34 are covered by the cover layer 40.

In some embodiments, the cover layer 40 includes an insulating material, and the insulating material may include organic material, inorganic material, or a combination thereof. The organic material may include epoxy resin, polyimide (PI), polybenzoxazole (PBO), silicone resin or combinations thereof, and the inorganic material may include silicon oxide (SiOx), silicon nitride (SixNy) or combinations thereof. In some embodiments, fillers may be added into the cover layer 40 so that the light beam L cannot penetrate. For example, black dispersed particles such as carbon black may be added to the cover layer 40 to make the cover layer 40 being black. In such way, an additional barrier wall may not necessarily be provided between the light-emitting element 20 and the light-sensing element 30 to avoid mutual interference. In some embodiments, in cross-sectional view, an outer sidewall of the cover layer 40 is flush with an outer sidewall of the driving element 10.

In some embodiments, the semiconductor device 1 further includes a plurality of first electrical connecting layers 50 and a plurality of second electrical connecting layers 60 located between the cover layer 40 and the driving element 10, so that the light-emitting element 20 can be electrically connected to the driving element 10 via the plurality of first electrical connecting layers 50, and the light-sensing element 30 can be electrically connected to the driving element 10 via the plurality of second electrical connecting layers 60. Specifically, the plurality of light-emitting contacts 24 of the light-emitting element 20 are respectively electrically connected to corresponding driving contacts 14 via different first electrical connecting layers 50, and the plurality of light-sensing contacts 34 of the light-sensing element 30 are respectively electrically connected to corresponding driving contacts 14 via different second electrical connecting layers 60. That is, each driving contact 14 is electrically connected to one light-emitting contact 24 or one light-sensing contact 34.

In some embodiments, the first electrical connecting layer 50 and the second electrical connecting layer 60 include a conductive material, such as metal, metal compound, other suitable conductive material, or combinations thereof. For example, the metal may include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), their alloys, or combinations thereof. For example, the metal compound may include tantalum nitride (TaN), titanium nitride (TiN), tungsten silicide (WSi₂), indium tin oxide (ITO), or the like.

In some embodiments, the first electrical connecting layers 50 and the second electrical connecting layers 60 may be formed as conductive films by deposition processes such as evaporation, sputtering, plating, screen printing, vacuum spraying, other suitable methods, or combinations thereof. Since the light-emitting element 20 and the light-sensing element 30 are electrically connected to the driving element 10 via conductive film-type connecting layers, compared with prior methods where the light-emitting element 20 and light-sensing element 30 are packaged first and then electrically connected to the driving element 10 via soldering, eutectic bonding, or adhesive processes, the present embodiments disclosed herein not only achieve high-precision electrical connection but also effectively reduce the overall volume of the components, satisfying the requirements for a thin profile.

In some embodiments, the driving contacts 14, the light-emitting contacts 24, the light-sensing contacts 34, the first electrical connecting layer 50, and the second electrical connecting layer 60 are completely covered by the cover layer 40. In such way, the contacts and electrical connecting layers can be protected from being affected by the external environment, and the cover layer 40 being opaque can prevent the contacts and electrical connecting layers from being visible to the user.

In some embodiments, the semiconductor device 1 further includes an intermediate layer 70 located between the cover layer 40 and the driving element 10. Specifically, the cover layer 40 covers the intermediate layer 70, and the intermediate layer 70 covers the driving element 10 so as to surround and cover both the light-emitting element 20 and the light-sensing element 30 located on the driving element 10. The plurality of first electrical connecting layers 50 and the plurality of second electrical connecting layers 60 are conformally located between the cover layer 40 and the intermediate layer 70. In some embodiments, the intermediate layer 70 includes a third opening 72 and a fourth opening 74. The third opening 72 is disposed correspondingly to the light-emitting element 20 to expose a portion of the light-emitting element 20, and the fourth opening 74 is disposed correspondingly to the light-sensing element 30 to expose a portion of the light-sensing element 30. Specifically, the third opening 72 is disposed correspondingly to the position of the first opening 42, so that a portion of the light-emitting element 20 is exposed through both the first opening 42 and the third opening 72. The fourth opening 74 is disposed correspondingly to the position of the second opening 44, so that a portion of the light-sensing element 30 is exposed through both the second opening 44 and the fourth opening 74. In other words, the first opening 42 and the third opening 72 overlap along the third direction D3, and the second opening 44 and the fourth opening 74 overlap along the third direction D3. In some embodiments, the width of the first opening 42 along the first direction D1 is less than or equal to the width of the third opening 72 along the first direction D1, and the width of the second opening 44 along the first direction D1 is less than or equal to the width of the fourth opening 74 along the first direction D1. That is, the vertical projection of the first opening 42 on the light-emitting element 20 locates within the area of the vertical projection of the third opening 72 on the light-emitting element 20, and the vertical projection of the second opening 44 on the light-sensing element 30 locates within the area of the vertical projection of the fourth opening 74 on the light-sensing element 30.

In some embodiments, the intermediate layer 70 further includes a plurality of first through-holes 71, a plurality of second through-holes 73, and a plurality of third through-holes 75. The plurality of first through-holes 71 respectively expose the corresponding light-emitting contacts 24, and each first electrical connecting layer 50 can be electrically connected to the corresponding light-emitting contact 24 via the corresponding first through-hole 71. The plurality of second through-holes 73 respectively expose the corresponding light-sensing contacts 34, and each second electrical connecting layer 60 can be electrically connected to the corresponding light-sensing contact 34 via the corresponding second through-hole 73. The plurality of third through-holes 75 respectively expose the corresponding driving contacts 14, and the first electrical connecting layer 50 and the second electrical connecting layer 60 can be electrically connected to the corresponding driving contacts 14 via the corresponding third through-holes 75. That is, each light-emitting contact 24 is electrically connected to one driving contact 14 via one first electrical connecting layer 50, and each light-sensing contact 34 is electrically connected to one driving contact 14 via one second electrical connecting layer 60. In some embodiments, the third opening 72 is located at a center position of the light-emitting element 20, e.g., between two first through-holes 71, and the fourth opening 74 is located at a center position of the light-sensing element 30, e.g., between two second through-holes 73.

In some embodiments, the intermediate layer 70 includes an insulating material, which may include organic material, inorganic material, or combinations thereof. The organic material may include epoxy resin, polyimide (PI), polybenzoxazole (PBO), silicone resin, or combinations thereof. The inorganic material may include silicon oxide (SiOx), silicon nitride (SixNy), or combinations thereof. In some embodiments, in a cross-sectional view, the outer sidewall of the cover layer 40, the outer sidewall of the intermediate layer 70, and the outer sidewall of the driving element 10 are flush with one another.

In some embodiments, the semiconductor device 1 further includes a first bonding layer 80 and a second bonding layer 90. The first bonding layer 80 is located between the driving element 10 and the light-emitting element 20 to enhance the bonding strength between the driving element 10 and the light-emitting element 20. The second bonding layer 90 is located between the driving element 10 and the light-sensing element 30 to enhance the bonding strength between the driving element 10 and the light-sensing element 30. The material of the first bonding layer 80 and the second bonding layer 90 may include epoxy resin, polyimide (PI), silicone resin, benzocyclobutene (BCB), or polyimide (PI).

In some embodiments, the semiconductor device 1 further includes a carrier substrate C configured to support the driving element 10. Specifically, the driving element 10 is located on the carrier substrate C, and both the light-emitting element 20 and the light-sensing element 30 are positioned on the side of the driving element 10 opposite to the carrier substrate C. In some embodiments, the carrier substrate C may be a package substrate, such as a ceramic substrate, glass substrate, or printed circuit board (PCB). In some embodiments, in a cross-sectional view, the outer sidewall of the carrier substrate C is not flush with the outer sidewall of the driving element 10. For example, a shortest distance along the first direction D1 between the outer sidewall of the carrier substrate C and the outer sidewall of the light-emitting element 20 is greater than a shortest distance along the first direction D1 between the outer sidewall of the driving element 10 and the outer sidewall of the light-emitting element 20.

FIG. 3 is an enlarged schematic view of the region A in FIG. 2 according to some embodiments of the present disclosure. In some embodiments, in a cross-sectional view, an inclined angle θ is formed between the outer sidewall of the light-emitting element 20 and the first direction D1, and the inclined angle θ ranges from 40°to 85°. If the inclined angle θ is less than 40°, it is disadvantageous for miniaturizing the device; if the inclined angle θ exceeds 85°, it's not easy for the intermediate layer 70 to fully cover the light-emitting element 20 and affect the subsequently conformally formed first electrical connecting layer 50 and may cause unstable internal electrical connections. In some embodiments, the outer sidewall of the light-sensing element 30 has a similar inclined shape and angle range as the light-emitting element 20, and thus will not be redundantly described herein.

In some embodiments, a portion of the light-emitting element 20 is embedded in the first bonding layer 80, so that part of the outer sidewall of the light-emitting element 20 is covered by the first bonding layer 80. Due to an increased contact area with the first bonding layer 80, an adhesion of the light-emitting element 20 to the first bonding layer 80 is improved. In some embodiments, an embedding depth d of the light-emitting element 20 in the first bonding layer 80 is less than or equal to 10 μm. When the embedding depth d exceeds 10 μm, it adversely affects the morphology and integrity of the intermediate layer 70 formed to cover the light-emitting element 20. In some embodiments, the bonding state and the embedding depth between the light-sensing element 30 and the second bonding layer 90 are the same or similar to those between the light-emitting element 20 and the first bonding layer 80, and are thus not redundantly described herein.

In some embodiments, when the light-emitting element 20 is a thin-film element, a thickness t of the light-emitting element 20 is a thickness summing the thickness of the light-emitting stacked layers 22 and the thickness of the light-emitting contacts 24. Here, the thickness is measured along the third direction D3. In some embodiments, the thickness t is less than 30 μm. In some embodiments, the morphology and thickness range of the light-sensing element 30 are the same or similar to those of the light-emitting element 20 and are thus not redundantly described herein.

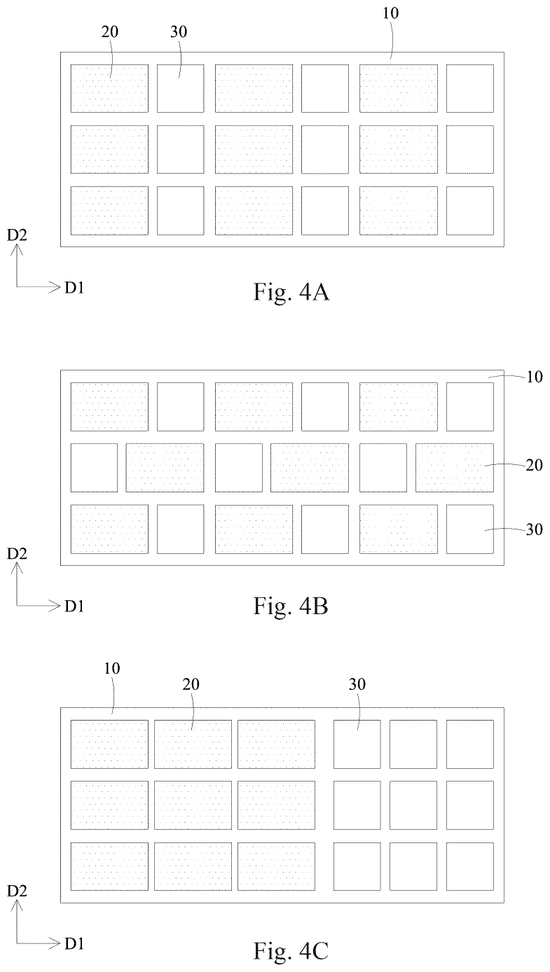

FIGS. 4A-4C are schematic diagrams illustrating the arrangement of the light-emitting elements 20 and the light-sensing elements 30 on the driving element 10 according to some embodiments of the present disclosure. Specifically, FIGS. 4A-4C illustrate the configurations of the plurality of light-emitting elements 20 and the plurality of light-sensing elements 30 on the driving element 10 when the number of light-emitting elements 20 is equal to the number of light-sensing elements 30. As shown in FIG. 4A, in some embodiments, an array including multiple light-emitting elements 20 and multiple light-sensing elements 30 is formed on the driving element 10. Specifically, in this array, one light-emitting element 20 and one light-sensing element 30 form a unit, and multiple units are spaced from one another and aligned along the first direction D1 and the second direction D2, so that the light-emitting elements 20 and the light-sensing elements 30 are alternately arranged along the first direction D1, the light-emitting elements 20 are adjacent to each other along the second direction D2, and the light-sensing elements 30 are adjacent to each other along the second direction D2. As shown in FIG. 4B, in some embodiments, an array including multiple light-emitting elements 20 and multiple light-sensing elements 30 is formed on the driving element 10. Specifically, one light-emitting element 20 and one light-sensing element 30 form a unit, multiple units are spaced from one another and aligned along the first direction D1, and multiple units are spaced and symmetrically arranged along the second direction D2, so that the light-emitting elements 20 and light-sensing elements 30 are adjacent to each other along both the first direction D1 and the second direction D2. As shown in FIG. 4C, in some embodiments, an array including multiple light-emitting elements 20 and multiple light-sensing elements 30 is formed on the driving element 10, where the light-emitting elements 20 are adjacently arranged along the first direction D1 and the second direction D2 to form a two-dimensional light-emitting array, the light-sensing elements 30 are adjacently arranged along the first direction D1 and the second direction D2 to form a two-dimensional light-sensing array, and the light-emitting array and light-sensing array are arranged side by side along the first direction D1 on the driving element 10.

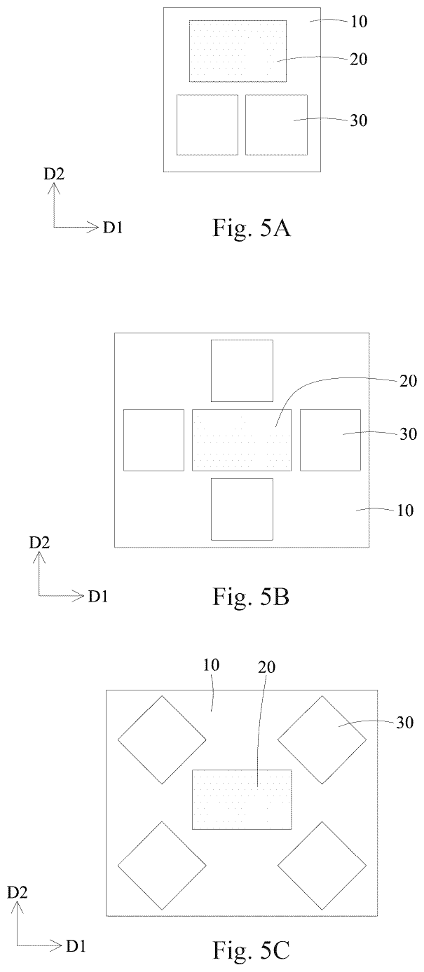

FIGS. 5A-5D are schematic diagrams illustrating the arrangement of the light-emitting elements 20 and the light-sensing elements 30 on the driving element 10 according to other embodiments of the present disclosure. Specifically, FIGS. 5A-5D illustrate the configurations of the light-emitting elements 20 and the light-sensing elements 30 on the driving element 10 when the number of light-emitting elements 20 is different from the number of light-sensing elements 30. As shown in FIG. 5A, in some embodiments, the number of light-emitting elements 20 on the driving element 10 is less than the number of light-sensing elements 30, and multiple light-sensing elements 30 are arranged on the same side of the light-emitting elements 20. In this embodiment, the number ratio of the number of light-emitting elements 20 to the number of the light-sensing elements 30 is 1:2. As shown in FIG. 5B, in some embodiments, the number of light-emitting elements 20 on the driving element 10 is less than the number of light-sensing elements 30, wherein a top view of one light-emitting element 20 has a polygonal shape, and the light-sensing elements 30 are arranged along the edges of the light-emitting element 20 so that the light-emitting element 20 is surrounded by the light-sensing elements 30. For example, when the light-emitting element 20 is quadrilateral, the light-sensing elements 30 are respectively arranged along the four sides of the quadrilateral, and the number ratio of light-emitting elements 20 to light-sensing elements 30 is 1:4. As shown in FIG. 5C, in some embodiments, the number of light-emitting elements 20 on the driving element 10 is less than the number of light-sensing elements 30, wherein a top view of the light-emitting element 20 is polygonal, and the light-sensing elements 30 are arranged correspondingly around the corners of the light-emitting element 20 so that the light-emitting element 20 is surrounded by the light-sensing elements 30. In this embodiment, the number ratio of the number of the light-emitting elements 20 to the number of the light-sensing elements 30 is 1:4. As shown in FIG. 5D, in some embodiments, the number of light-emitting elements 20 on the driving element 10 is less than the number of light-sensing elements 30, wherein the light-emitting element 20 is located in a central region of the driving element 10, and the light-sensing elements 30 are arranged along a periphery of the driving element 10 so that the light-emitting element 20 is surrounded by the light-sensing elements 30.

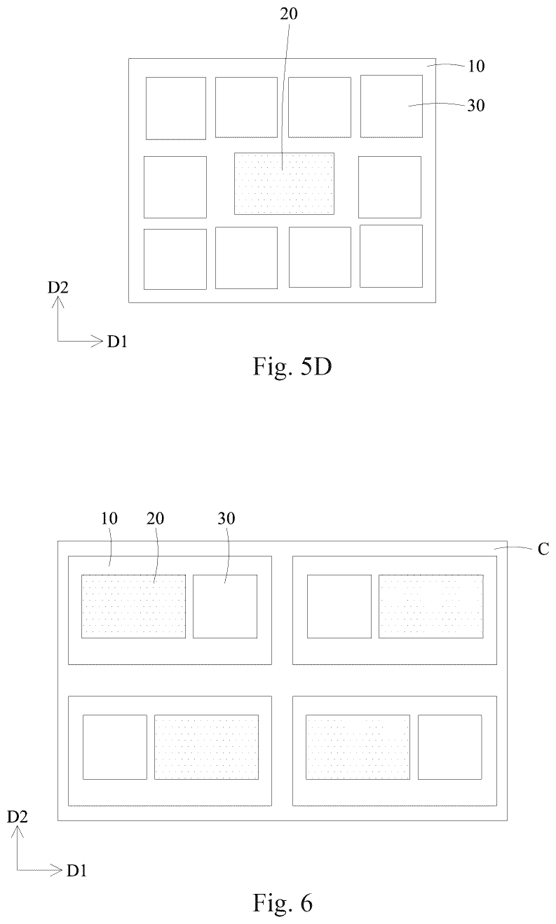

FIG. 6 is a schematic diagram illustrating the arrangement of the light-emitting elements 20, the light-sensing elements 30, and the driving elements 10 on the carrier substrate C according to some embodiments of the present disclosure. In some embodiments, a two-dimensional array including multiple driving elements 10 arranged with spacing on the carrier substrate C, and a light-emitting element 20 and a light-sensing element 30 is disposed on each driving element 10. The light-emitting elements 20 and light-sensing elements 30 on two adjacent driving elements 10 are arranged to be symmetrical to each other. In other embodiments, the arrangement of the light-emitting elements 20 and light-sensing elements 30 on two adjacent driving elements 10 may also be the same.

In summary, embodiments of the present disclosure integrate thin-film light-emitting elements and thin-film light-sensing elements onto the driving element, and use electrically conductive film-type electrical connection layers to form electrical connections between the light-emitting elements, the light-sensing elements, and the driving element. Such configuration not only enables highly precise electrical connection circuits but also effectively reduces an overall volume of the component to meet the thinning requirements, for example, in applications such as sensing fields or optical communication fields (e.g., silicon photonics). In addition, embodiments of the present disclosure utilize a light-blocking covering layer to simultaneously encapsulate the light-emitting elements and the light-sensing elements onto the driving element, while only forming openings corresponding to the positions of the light-emitting elements and light-sensing elements for light emission and light reception. Therefore, there is no need to provide partition walls, and interference between the light-emitting elements and the light-sensing elements can be avoided, thereby achieving the effect of process simplification.

Several components of the embodiments have been summarized above so that those having ordinary knowledge in the technical field to which the present disclosure pertains can better understand the concepts of the embodiments of the present disclosure. Those having ordinary knowledge in the technical field to which the present disclosure pertains should understand that, based on the embodiments of the present disclosure, they can design or modify other processes and structures to achieve the same purposes and/or advantages as those of the embodiments introduced herein. Those having ordinary knowledge in the technical field to which the present disclosure pertains should also understand that such equivalent structures do not depart from the spirit and scope of the present disclosure, and that they may make various modifications, substitutions, and replacements without departing from the spirit and scope of the present disclosure. Accordingly, the scope of protection of the present disclosure shall be determined by the scope defined in the appended claims. Furthermore, although the present disclosure has been disclosed above by way of several preferred embodiments, it is not intended to limit the present disclosure.

References to features, advantages, or similar language throughout the present specifications are not intended to mean that all such features and advantages that may be realized through the present disclosure should or must be realized in any single embodiment of the present disclosure. Rather, language referring to the features and advantages is to be understood as meaning that specific features, advantages, or characteristics described in connection with an embodiment are included in at least one embodiment of the present disclosure. Therefore, discussions of features, advantages, and similar language throughout the specifications may, but do not necessarily, refer to the same embodiment.

Furthermore, in one or more embodiments, the features, advantages, and characteristics described in the present disclosure may be combined in any suitable manner. Based on the descriptions herein, persons skilled in the relevant art will recognize that the present disclosure can be realized without one or more specific features or advantages of a particular embodiment. In other cases, additional features and advantages may be recognized in certain embodiments that may not be present in all embodiments of the present disclosure.

What is claimed is:

1. A semiconductor device comprising:
a driving element;
a light-emitting element and a light-sensing element arranged side by side on the driving element;
a cover layer configured to cover the light-emitting element, the light-sensing element, and the driving element; and
a plurality of first electrical connecting layers and a plurality of second electrical connecting layers disposed between the cover layer and the driving element, the light-emitting element being electrically connected to the driving element via the first electrical connecting layers, and the light-sensing element being electrically connected to the driving element via the second electrical connecting layers;
wherein the cover layer comprises a first opening and a second opening, the first opening is disposed on the light-emitting element to expose a portion of the light-emitting element, and the second opening is disposed on the light-sensing element to expose a portion of the light-sensing element.

2. The semiconductor device of claim 1, further comprising an intermediate layer disposed between the cover layer and the driving element, wherein the first electrical connecting layers and the second electrical connecting layers are disposed between the cover layer and the intermediate layer.

3. The semiconductor device of claim 2, wherein the intermediate layer comprises a plurality of first through-holes and a plurality of second through-holes, the first through-holes partially exposes the light-emitting element, the second through-holes partially exposes the light-sensing element, the first electrical connecting layers are electrically connected to the light-emitting element via the first through-holes, and the second electrical connecting layers are electrically connected to the light-sensing element via the second through-holes.

4. The semiconductor device of claim 3, wherein the intermediate layer further comprises a plurality of third through-holes, the third through-holes expose a portion of the driving element, the first electrical connecting layers and the second electrical connecting layers are electrically connected to the driving element via the third through-holes.

5. The semiconductor device of claim 3, wherein the first through-holes are separated from the first opening, and the second through-holes are separated from the second opening.

6. The semiconductor device of claim 1, wherein an angle between a sidewall of the light-emitting element and a first direction ranges from 40°to 85°.

7. The semiconductor device of claim 6, wherein the light-emitting element and the light-sensing element are arranged along the first direction.

8. The semiconductor device of claim 1, further comprising a first bonding layer and a second bonding layer, the first bonding layer being positioned between the light-emitting element and the driving element, and the second bonding layer being positioned between the light-sensing element and the driving element.

9. The semiconductor device of claim 8, wherein a portion of the light-emitting element is embedded in the first bonding layer such that a portion of a sidewall of the light-emitting element is covered by the first bonding layer.

10. The semiconductor device of claim 9, wherein the light-emitting element is embedded in the first bonding layer to a depth of less than or equal to 10 μm.

11. The semiconductor device of claim 1, wherein the cover layer is opaque for a light emitted from the light-emitting element.

12. The semiconductor device of claim 2, wherein the intermediate layer comprises a third opening and a fourth opening, the third opening is overlapped with the first opening, and the fourth opening is overlapped with the second opening.

13. The semiconductor device of claim 12, wherein a width of the first opening is less than or equal to a width of the third opening, and a width of the second opening is less than or equal to a width of the fourth opening.

14. The semiconductor device of claim 12, wherein the first opening locates within an area of the third opening, and the second opening locates within an area of the fourth opening.

15. The semiconductor device of claim 12, wherein the third opening is located at a center position of the light-emitting element, and the fourth opening is located at a center position of the light-sensing element.

16. The semiconductor device of claim 3, wherein the light-emitting element comprises a plurality of light-emitting contacts exposed from the first through-holes and the light-sensing element comprises a plurality of light-sensing contacts exposed from the second through-holes.

17. The semiconductor device of claim 16, wherein the first opening is located between two light-emitting contacts, and the second opening is located between two light-sensing contacts.

18. The semiconductor device of claim 16, wherein the light-emitting contacts and the light-sensing contacts are covered by the cover layer.

19. The semiconductor device of claim 4, wherein the driving element comprises a plurality of driving contacts exposed from the third through-holes.

20. A semiconductor apparatus comprising:
a carrier substrate; and
a plurality of semiconductor devices of claim 1 disposed on the carrier substrate;
wherein the plurality of semiconductor devices is arranged in a two-dimensional array.
